(19) United States
(12) Patent Application Publication
(10) Pub. No.: US 2019/0071777 A1
(43) Pub. Date: Mar. 7, 2019

(54) SUBSTRATE PROCESSING APPARATUS

(71) Applicant: KOKUSAI ELECTRIC CORPORATION, Tokyo (JP)

(72) Inventors: Hidenari YOSHIDA, Toyama-shi (JP); Takafumi SASAKI, Toyama-shi (JP); Hidetoshi MIMURA, Toyama-shi (JP); Yusaku OKAJIMA, Toyama-shi (JP)

(73) Assignee: KOKUSAI ELECTRIC CORPORATION, Tokyo (JP)

(21) Appl. No.: 16/116,603

(22) Filed: Aug. 29, 2018

(30) Foreign Application Priority Data
Sep. 5, 2017 (JP) 2017-170340

(51) Int. Cl. C23C 16/455; H01L 21/67; H01L 21/673; C23C 16/458; C23C 16/34; C23C 16/44

(52) U.S. Cl. CPC C23C 16/45578; H01L 21/67017; C23C 16/4412; C23C 16/4583; C23C 16/345; H01L 21/6732

(57) ABSTRACT

Described herein is a technique capable of improving uniformity between substrates. According to the technique, there is provided a substrate processing apparatus including: a substrate retainer including a product wafer support region for supporting product wafers with patterns in a stacked state, an upper dummy wafer support region for supporting dummy wafers above the product wafer support region, and a lower dummy wafer support region for supporting dummy wafers below the product wafer support region; a process chamber accommodating the substrate retainer; a gas supply system for supplying a gas to the substrate retainer, including a tubular nozzle vertically extending along the substrate retainer, and a gas supply port provided at the nozzle; and an exhaust system for exhausting an atmosphere of the process chamber. An upper end of the gas supply port is located lower than an uppermost dummy wafer supported in the upper dummy wafer support region.

### CROSS-REFERENCE TO RELATED PATENT APPLICATION

This non-provisional U.S. patent application claims priority under 35 U.S.C. § 119 of Japanese Patent Application No. 2017-170340, filed on Sep. 5, 2017, in the Japanese Patent Office, the entire contents of which are hereby incorporated by reference.

### BACKGROUND

### 1. Field

The present invention relates to a substrate processing apparatus.

### 2. Description of the Related Art

In a manufacturing process of a semiconductor device, for example, a vertical type substrate processing apparatus that batch-processes (i.e., processes collectively) substrates is used. The vertical type substrate processing apparatus is configured to supply a gas to each of the substrates by using a porous nozzle extending vertically along the plurality of substrates.

However, in the vertical type substrate processing apparatus using the porous nozzle, processed state may not be uniform between the substrates.

### SUMMARY

Described herein is a technique capable of improving uniformity between substrates.

According to one aspect of the technique described herein, there is provided a substrate processing apparatus including: a substrate retainer including a product wafer support region for supporting product wafers with patterns in a stacked state, an upper dummy wafer support region for supporting dummy wafers above the product wafer support region, and a lower dummy wafer support region for supporting dummy wafers below the product wafer support region; a process chamber accommodating the substrate retainer; a gas supply system for supplying a gas to the substrate retainer, including a tubular nozzle vertically extending along the substrate retainer, and a gas supply port provided at the nozzle; and an exhaust system for exhausting an atmosphere of the process chamber. An upper end of the gas supply port is located lower than an uppermost dummy wafer supported in the upper dummy wafer support region.

### BRIEF DESCRIPTION OF THE DRAWINGS

FIG. 1 schematically illustrates a vertical cross-section of a substrate processing apparatus according to an embodiment described herein.

FIG. 2 schematically illustrates a horizontal cross-section of a process furnace of the substrate processing apparatus according to the embodiment.

FIGS. 3A and 3B schematically illustrate nozzles preferably used in the embodiment.

FIG. 4 schematically illustrates an exemplary gas flow to wafers.

FIGS. 5A and 5B schematically illustrate an exemplary simulation result of a partial pressure distribution of a gas when the gas is supplied to the wafers.

### DETAILED DESCRIPTION

### Embodiment

Hereinafter, an embodiment will be described below by way of a non-limiting example with reference to the accompanying drawings. In the drawings, like reference numerals represent like components and detailed descriptions of redundant components will be omitted.

(1) Configuration of Substrate Processing Apparatus

First, a schematic configuration of a substrate processing apparatus according to the embodiment will be described. The substrate processing apparatus, which is described by way of an example in the embodiment, is configured to perform a substrate processing such as a film-forming process described later, which is one of the manufacturing processes in a method of manufacturing a semiconductor device. The substrate processing apparatus includes a vertical type substrate processing apparatus 2 (hereinafter, also referred to simply as a “processing apparatus”) configured to batch-process (i.e., process collectively) a plurality of substrates.

<Reaction Tube>

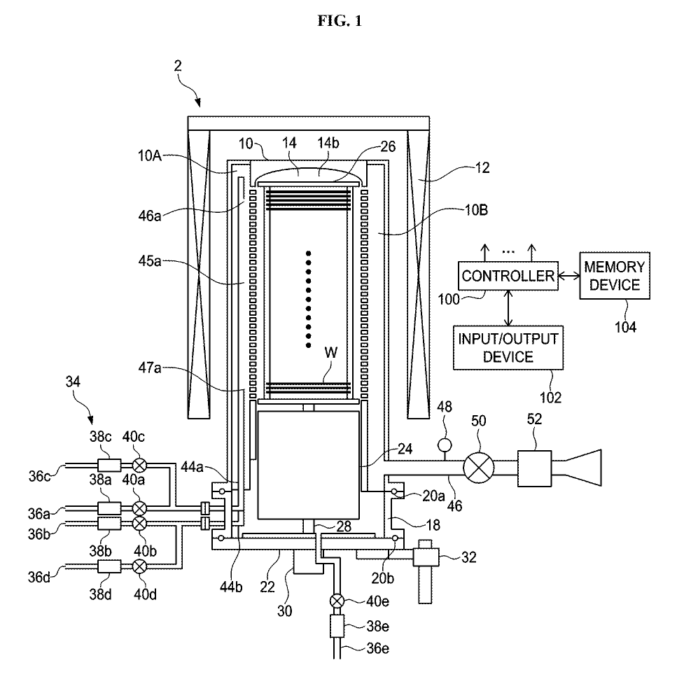

As shown in FIG. 1, the processing apparatus 2 includes a cylindrical reaction tube 10. The reaction tube 10 is made of a material having heat resistance and corrosion resistance such as quartz and silicon carbide (SiC).

The process chamber 14 where wafers W serving as substrates are processed is provided in the reaction tube 10. A heater 12 serving as a heating device (heating mechanism) is provided on an outer periphery of the reaction tube 10. The heater 12 is configured to heat an inside of the process chamber 14.

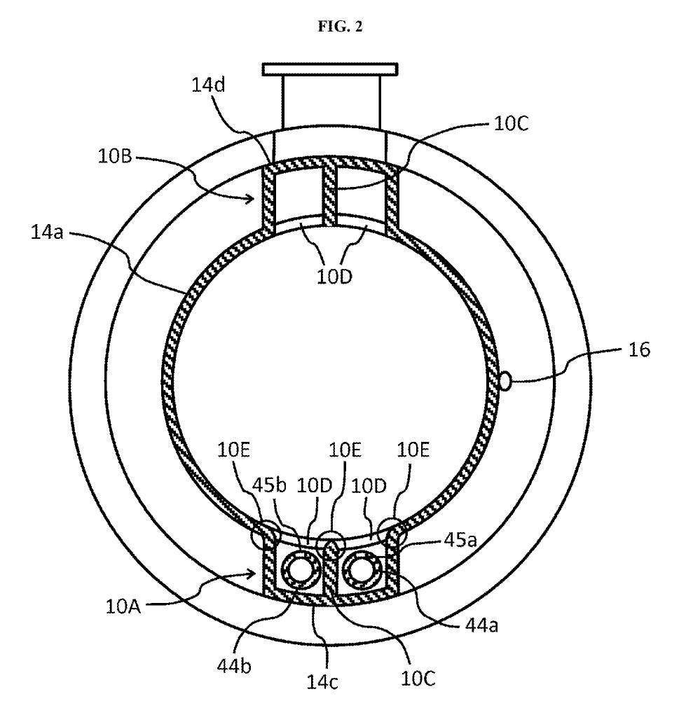

As shown in FIG. 2, a supply buffer chamber 10A serving as a gas supply chamber and an exhaust buffer chamber 10B are provided in the reaction tube 10 so as to face each other. The supply buffer chamber 10A and the exhaust buffer chamber 10B protrude outward from the reaction tube 10. The interior of the supply buffer chamber 10A and the interior of the exhaust buffer chamber 10B are partitioned into a plurality of spaces by partition walls 10C, respectively. Nozzles 44a and 44b described later are provided respectively in the plurality of spaces partitioned from the supply buffer chamber 10A. Horizontally elongated slits 10D are provided on inner walls of the supply buffer chamber 10A and the exhaust buffer chamber 10B, respectively. That is, the slits 10D are provided on inner walls so as to face the process chamber 14. End portions 10E facing the process chamber 14 (that is, end portions of side walls of the supply buffer chamber 10A facing the process chamber 14 and an end portion of the partition wall 10C provided at the supply buffer chamber 10A facing the process chamber 14) are rounded rather than angled as described later. Thereby, preferably, an outlet portion of the supply buffer chamber 10A facing the process chamber 14 is tapered when viewed from above. A temperature detector 16 serving as a temperature detecting mechanism is provided vertically along an outer wall of the reaction tube 10.

As shown in FIG. 1, a cylindrical manifold 18 is connected to an opening portion at a lower end of the reaction tube 10 via a sealing member 20a such as an O-ring. The manifold 18 supports the reaction tube 10 from thereunder. The manifold 18 is made of a metal such as stainless steel. An opening portion at a lower end of the manifold 18 may be opened or closed by a disk-shaped lid 22. For example, the lid 22 is made of a metal. A sealing member 20b such as an O-ring is provided on an upper surface of the lid 22. The reaction tube 10 is hermetically sealed by the sealing members 20a and 20b. A heat insulating portion 24 is provided on the lid 22. A hole (not shown) is provided vertically at a center portion of the heat insulating portion 24. The heat insulating portion 24 is made of, for example, quartz.

<Process Chamber>

The process chamber 14 provided in the reaction tube 10 is configured to process the wafers W as substrates. A boat 26 serving as a substrate retainer can be accommodated in the process chamber 14. The process chamber 14 is constituted by a cylindrical portion 14a surrounding an outer peripheral portion of the boat 26, a flat plate-shaped lid 14b configured to close an upper end of the cylindrical portion 14a, a storage body 14c protruding outward from a first side portion of the cylindrical portion 14a to define the supply buffer chamber 10A serving as a blocking space and accommodating the nozzles 44a and 44b, and a duct body 14d protruding outward from a second side portion of the cylindrical portion 14a opposite to the first side portion to define the exhaust buffer chamber 10B serving as a blocked exhaust path. The cylindrical portion 14a, the lid 14b, the storage body 14c and the duct body 14d are formed as an integrated body made of a material having heat resistance and corrosion resistance such as quartz and silicon carbide (SiC).

A diameter of the cylindrical portion 14a constituting the process chamber 14 is so small that the nozzles 44a and 44b cannot be inserted in a gap between the cylindrical portion 14a and the wafers W (particularly, product wafers Wp described later) accommodated in the process chamber 14 coaxially with the cylindrical portion 14a.

<Boat>

The boat 26 serving as a substrate retainer and accommodated in the process chamber 14 supports the wafers W (e.g. 25 to 150 wafers) in vertical direction while the wafers W are supported in a stacked state with a predetermined interval therebetween. The boat 26 is made of a material such as quartz and silicon carbide (SiC).

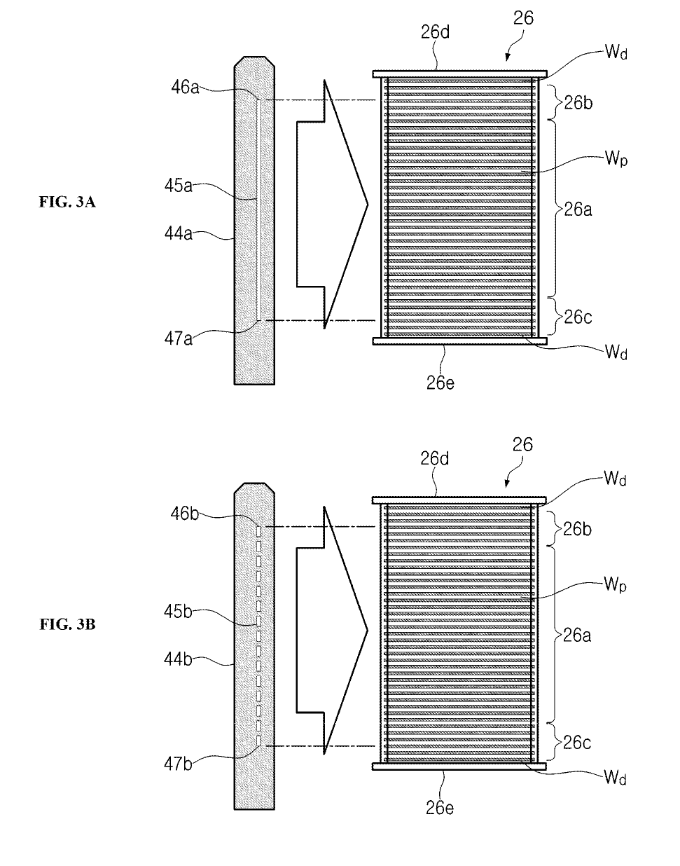

As shown in FIGS. 3A and 3B, the boat 26 includes a product wafer support region 26a, an upper dummy wafer support region 26b, and a lower dummy wafer support region 26c, as regions for supporting the wafers W. The product wafer support region 26a refers to a region of the boat 26 where product wafers Wp with patterns formed thereon are supported in a stacked state. The upper dummy wafer support region 26b refers to a region above the product wafer support region 26a where dummy wafers Wd without pattern are supported. The lower dummy wafer support region 26c refers to a region below the product wafer support region 26a where other dummy wafers Wd without pattern are supported.

As shown in FIG. 1, the boat 26 is supported above the heat insulating portion 24 by a rotating shaft 28 penetrating the lid 22 and the heat insulating portion 24. For example, a magnetic fluid seal (not shown) is provided at a portion where the rotating shaft 28 penetrates the lid 22. The rotating shaft 28 is connected to a rotating mechanism 30 provided below the lid 22. As a result, it is possible to rotate the boat 26 by the rotating mechanism 30 while the inside of the process chamber 14 is hermetically sealed.

The lid 22 is elevated or lowered by a boat elevator 32 serving as an elevating mechanism. As a result, the boat 26 is loaded into or unloaded from the process chamber 14 in the reaction tube 10 by elevating or lowering the boat 26 together with the lid 22 by the boat elevator 32.

<Gas Supply Mechanism>

The processing apparatus 2 includes a gas supply mechanism 34 serving as a gas supply system and configured to supply gases used for the substrate processing described later into the process chamber 14. The gases supplied by the gas supply mechanism 34 may be changed depending on the type of a film to be formed. According to the embodiment, for example, the gas supply mechanism 34 includes a source gas supply system, a reactive gas supply system and an inert gas supply system.

The source gas supply system includes a gas supply pipe 36a connected to a source gas supply source (not shown). A mass flow controller (MFC) 38a serving as a flow rate controller (flow rate control mechanism) and a valve 40a serving as an opening/closing valve are provided at the gas supply pipe 36a in order from the upstream side to the downstream side of the gas supply pipe 36a. The gas supply pipe 36a is connected to the nozzle 44a which penetrates a side wall of the manifold 18. The nozzle 44a is provided in the supply buffer chamber 10A and vertically extends in the supply buffer chamber 10A. The nozzle 44a is tubular (pipe-shaped). The nozzle 44a is provided with a vertically elongated slit 45a serving as a gas supply port opening toward the wafers W supported by the boat 26. A source gas supplied by the source gas supply system is diffused into the supply buffer chamber 10A through the slit 45a of the nozzle 44a and is supplied to the wafers W through the slits 10D of the supply buffer chamber 10A. The source gas supply system may further include the nozzle 44a and the slit 45a. The nozzle 44a will be described later in detail.

The reactive gas supply system is configured similarly to the source gas supply system. The reactive gas supply system includes a gas supply pipe 36b connected to a reactive gas supply source (not shown), a mass flow controller (WC) 38b and a valve 40b. The reactive gas supplied by the source gas supply system from the reactive gas supply source is supplied to the wafers W through the nozzle 44b and the slits 10D. The nozzle 44b is provided in the supply buffer chamber 10A and vertically extends in the supply buffer chamber 10A. The nozzle 44b is tubular (pipe-shaped). The nozzle 44b is provided with a plurality of gas supply holes 45b serving as a gas supply port opening toward the wafers W supported by the boat 26. The reactive gas supply system may further include the nozzle 44b and the plurality of gas supply holes 45b.

The inert gas supply system includes gas supply pipes 36c and 36d connected to the gas supply pipes 36a and 36b, respectively, and mass flow controllers (MFCs) 38c and 38d and valves 40c and 40d provided at the gas supply pipes 36c and 36d, respectively. The inert gas supply system may further include the nozzles 44a and 44b, the slit 45a and the plurality of gas supply holes 45b. An inert gas supplied by the inert gas supply system from an inert gas supply source (not shown) is supplied to the wafers W through the nozzles 44a and 44b and the slits 10D. The inert gas serves as a carrier gas or a purge gas.

The inert gas supply system further includes a gas supply pipe 36e penetrating the lid 22 and a mass flow controller (MFC) 38e and a valve 40e provided at the supply pipe 36e. An inert gas supplied by the inert gas supply system from an inert gas supply source (not shown) is supplied into the reaction tube 10 in order to prevent the gas such as the source gas and the reactive gas supplied into the process chamber 14 from flowing into the heat insulating portion 24.

<Exhaust System>

An exhaust pipe 46 is provided at the reaction tube 10. The exhaust pipe 46 is connected to the exhaust buffer chamber 10B. A vacuum pump 52, which is a vacuum exhaust device, is connected to the exhaust pipe 46 through a pressure sensor 48 serving as a pressure detecting device (pressure detecting mechanism) and an APC (automatic pressure controller) valve 50 serving as a pressure adjusting device (pressure controller). The pressure sensor 48 is configured to detect an inner pressure of the process chamber 14. The inner pressure of the process chamber 14 can be adjusted to a pressure suitable for the substrate processing by these components. An exhaust system is constituted by the exhaust pipe 46, the pressure sensor 48 and the APC valve 50. The exhaust system may further include the vacuum pump 52.

<Controller>

A controller 100 is electrically connected to and controls the rotating mechanism 30, the boat elevator 32, the MFCs 38a through 38e and the valves 40a through 40e of the gas supply mechanism 34 and the APC valve 50. For example, the controller 100 is embodied by a microprocessor (computer) having a CPU (Central Processing Unit), and is configured to control the operations of the processing apparatus 2. An input/output device 102 such as a touch panel is connected to the controller 100.

A memory device 104, which is a recording medium, is connected to the controller 100. A control program for controlling the operations of the processing apparatus 2 or a program (also referred to as a “recipe program”) for controlling the components of the processing apparatus 2 according to process conditions to perform a processing is readably stored in the memory device 104.

The memory device 104 may be embodied by a built-in memory device (such as a hard disk and a flash memory) of the controller 100 or a portable external recording device (e, g, magnetic tapes, magnetic disks such as a flexible disk and a hard disk, optical discs such as a CD and a DVD, magneto-optical discs such as a MO, and semiconductor memories such as a USB memory and a memory card). The program may be provided to the computer using a communication means such as the Internet and a dedicated line. The program such as the recipe program is read from the memory device 104 by instructions such as input from the input/output device 102. The processing apparatus 2 performs a desired processing according to the recipe program under the control of the controller 100 when the controller 100 executes the recipe program.

Next, a process for forming a film on the wafers W serving as substrates (also referred to as “film-forming process”) using the above-described processing apparatus 2 will be described. The film-forming process is one of the manufacturing processes in a method of manufacturing a semiconductor device. Hereinafter, the film-forming process will be described by way of an example wherein a silicon nitride (SiN) film is formed on the wafers W by supplying HCDS (Si₂Cl₆: hexachlorodisilane) serving as the source gas and ammonia (NH₃) gas serving as the reactive gas to the wafers W. In the following description, the controller 100 controls the operations of components of the processing apparatus 2.

<Wafer Charging and Boat Loading Step>

When processing the wafers W, firstly, the wafers W are charged into the boat 26 (wafer charging). In the wafer charging and boat loading step, the dummy wafers Wd are charged into the upper dummy wafer support region 26b and the lower dummy wafer support region 26c. The product wafers Wp with patterns formed thereon are charged into the product wafer support region 26a between the upper dummy wafer support region 26b and the lower dummy wafer support region 26c. In order to improve uniformity between the product wafers Wp and to prevent the processed state from being non-uniform between the product wafers Wp, the dummy wafers Wd are provided above and below the product wafers Wp. The number of the dummy wafers Wd charged into the boat 26 (i.e., the number of the dummy wafers Wd charged into the upper dummy wafer support region 26b and the lower dummy wafer support region 26c) is not particularly limited and can be determined appropriately. As the dummy wafers Wd, bare wafers that no pattern is formed thereon may be used.

After the product wafers Wp and the dummy wafers Wd are charged into each region of the boat 26 (wafer charging), the boat 26 is loaded into the process chamber 14 by the boat elevator 32 (boat loading). Then, the lid 22 air-tightly seals the opening portion at the lower end of the reaction tube 10.

<Pressure and Temperature Adjusting Step>

After the wafer charging and boat loading step is completed, in the pressure and temperature adjusting step, the vacuum pump 52 vacuum-exhausts (depressurizes and exhausts) the inside of the process chamber 14 until the inner pressure of the process chamber 14 reaches a predetermined pressure (vacuum level). The inner pressure of the process chamber 14 is measured by the pressure sensor 48, and the APC valve 50 is feedback-controlled based on the measured pressure. The heater 12 heats the process chamber 14 until the temperature of the wafers W in the process chamber 14 reaches a predetermined temperature. In the pressure and temperature adjusting step, the energization state of the heater 12 is feedback-controlled based on the temperature detected by the temperature detector 16 such that the temperature of the process chamber 14 satisfies a predetermined temperature distribution. The rotating mechanism 30 starts to rotate the boat 26 and the wafers W.

<Film-Forming Process>

After the temperature of the process chamber 14 is stabilized at a predetermined processing temperature, the film-forming process is performed on the wafers W in the process chamber 14. In the film-forming process, a cycle including a source gas supply step, a source gas exhaust step, a reactive gas supply step and a reactive gas exhaust step are performed a predetermined number of time (one or more times).

<Source Gas Supply Step>

First, the HCDS gas is supplied to the wafers W in the process chamber 14. The flow rate of the HCDS gas is adjusted to a desired flow rate by the MFC 38a. The HCDS gas having the flow rate thereof adjusted is supplied into the process chamber 14 via the gas supply pipe 36a, the nozzle 44a and the slits 10D. In the source gas supply step, when the outlet portion of the supply buffer chamber 10A accommodating the nozzle 44a is tapered, it is possible to suppress the generation of a turbulent flow of the HCDS gas when the HCDS gas is discharged through the slits 10D. For example, if the end portions 10E at the outlet portion of the supply buffer chamber 10A are angled rather than rounded, the turbulent flow may be generated not only in the lateral direction when viewed from above but also in the vertical direction along which the wafers W are stacked. As a result, the amount of the HCDS gas supplied into the process chamber 14 may be non-uniform in the vertical direction. However, when the outlet portion of the supply buffer chamber 10A is tapered, it is possible to suppress the turbulent flow when the HCDS gas is discharged through the slits 10D. As a result, it is possible to supply the HCDS gas in a manner that the supplied amount of the HCDS gas is uniform between the wafers W.

<Source Gas Exhaust Step>

Next, the supply of the HCDS gas is stopped, and the vacuum pump 52 vacuum-exhausts the inside of the process chamber 14. Simultaneously, N₂ gas serving as an inert gas may be supplied into the process chamber 14 through the inert gas supply system (purge by inert gas).

<Reactive Gas Supply Step>

Next, the NH₃ gas is supplied to the wafers W in the process chamber 14. The flow rate of the NH₃ gas is adjusted to a desired flow rate by the MFC 38b. The NH₃ gas having the flow rate thereof adjusted is supplied into the process chamber 14 via the gas supply pipe 36b, the nozzle 44b and the slits 10D. In the reactive gas supply step, when the outlet portion of the supply buffer chamber 10A accommodating the nozzle 44b is tapered, it is possible to suppress the generation of a turbulent flow of the NH₃ gas when the NH₃ gas is discharged through the slits 10D. For example, if the end portions 10E at the outlet portion of the supply buffer chamber 10A are angled rather than rounded, the turbulent flow may be generated not only in the lateral direction when viewed from above but also in the vertical direction along which the wafers W are stacked, and as a result, the amount of the NH₃ gas supplied into the process chamber 14 may be non-uniform in the vertical direction. However, when the outlet portion of the supply buffer chamber 10A is tapered, it is possible to suppress the turbulent flow when the NH₃ gas is discharged through the slits 10D. As a result, it is possible to supply the NH₃ uniformly between the wafers W.

<Reactive Gas Exhaust Step>

Next, the supply of the NH₃ gas is stopped, and the vacuum pump 52 vacuum-exhausts the inside of the process chamber 14. Simultaneously, the N₂ gas may be supplied into the process chamber 14 through the inert gas supply system (purge by inert gas).

By performing the cycle including the four steps described above the predetermined number of time (one or more times), it is possible to form a SiN film having a predetermined composition and a predetermined thickness on the wafers W.

<Boat Unloading and Wafer Discharging Step>

After the SiN film having the predetermined thickness is formed, the N₂ gas is supplied by the inert gas supply system to replace the inner atmosphere of the process chamber 14 with the N₂ gas, and the pressure of the process chamber 14 is returned to atmospheric pressure. The lid 22 is then lowered by the boat elevator 32 and the boat 26 is unloaded from the reaction tube 10 (boat unloading). Thereafter, the processed wafers W are discharged from the boat 26 (wafer discharging).

For example, the process conditions for forming the SiN film on the wafers W are as follows:

Processing temperature (wafer temperature): 300° C. to 700° C.;

Processing pressure (the inner pressure of the process chamber): 1 Pa to 4,000 Pa;

Flow rate of HCDS gas: 100 sccm to 10,000 sccm;

Flow rate of NH₃ gas: 100 sccm to 10,000 sccm; and

Flow rate of N₂ gas: 100 sccm to 10,000 sccm.

By selecting suitable values within these processing conditions, the film-forming process can be performed properly.

(3) Detailed Configurations for Supplying Gas

Hereinafter, configurations for supplying the gas such as the source gas and the reactive gas into the process chamber 14, particularly the nozzles 44a and 44b configured to supply the gas, will be described in detail.

<Dummy Wafer Loading>

Before the gas is supplied supply into the process chamber 14 as described above, the boat 26 is loaded into the process chamber 14. The dummy wafers Wd are charged in the upper dummy wafer support region 26b and a lower dummy wafer support region 26c of the boat 26, respectively, before the boat 26 is loaded into the process chamber 14.

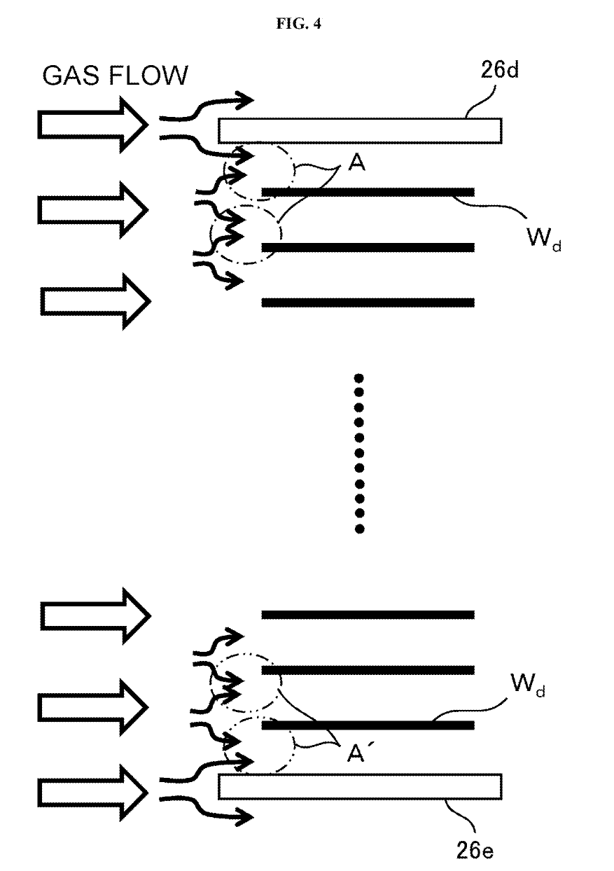

As shown in FIG. 4, in the boat 26 with the wafers W charged as described above, a top plate 26d of the boat 26 is provided above an uppermost dummy wafer Wd supported in the upper dummy wafer support region 26b so as to be adjacent to the uppermost dummy wafer Wd, and a bottom plate 26e of the boat 26 is provided below a lowermost dummy wafer Wd supported in the lower dummy wafer support region 26c so as to be adjacent to the lowermost dummy wafer Wd.

When the gas supply is supplied, if there is an obstacle in a traveling direction of the gas, a turbulent flow of the gas is generated due to collision with the obstacle. The generated turbulent flow varies in size depending on an area of the collision. For example, the size of the generated turbulent flow differs at each location of the boat 26 because the size of the area of the collision differs when the gas collides with the top plate 26d of the boat 26 and when the gas collides with the wafers W.

If the dummy wafers Wd are not charged in the boat 26 and the product wafers Wp are charged to an adjacent region of the top plate 26d of the boat 26, due to the difference in the size of the generated turbulent flow, the amount of the gas supplied to an uppermost product wafer Wp supported in an uppermost portion of the boat 26 (i.e., a portion directly below the top plate 26d) may be different from that of the gas supplied to a product wafer Wp supported in the vicinity of a center portion of the boat 26 (Refer to “A” in FIG. 4). The difference in the supplied amount of the gas makes the processed state be non-uniform between the product wafers Wp in the boat 26, which leads to a decrease in the yield of the substrate processing to the product wafers Wp. Thus, the difference in the supplied amount of the gas should be avoided in advance.

The same phenomenon occurs not only in the vicinity of the top plate 26d of the boat 26 but also in the vicinity of the bottom plate 26e of the boat 26 (Refer to “A′” in FIG. 4).

Therefore, according the embodiment, the dummy wafers Wd are arranged in each of the upper dummy wafer support region 26b and the lower dummy wafer support region 26c, which are regions susceptible to the influence of the difference in the size of the turbulent flow. Thus, it is possible to improve the uniformity of the amount of the supplied gas between the product wafers Wp, thereby, it is possible to suppress the decrease in the yield of the substrate processing for the product wafers Wp.

<Position of End Portion of Nozzle>

As described above, in the embodiment, the dummy wafers Wd are used to avoid the influence of the difference in the size of the turbulent flow on the product wafers Wp. However, the non-uniformity between the product wafers Wp cannot be completely corrected by merely using the dummy wafers Wd.

In order to correct the non-uniformity between the product wafers Wp, for example, it is possible to suppress the difference in the size of the turbulent flow by preventing the gas flow from colliding with the top plate 26d or the bottom plate 26e of the boat 26. Therefore, in the embodiment, the nozzles 44a and 44b for supplying the gas into the process chamber 14 are configured as described below.

Specifically, as shown in FIG. 3A, in the nozzle 44a, an upper end 46a of the slit 45a (also referred to as an upper end 46a of the gas supply port) is located at a position lower than the uppermost dummy wafer Wd supported in the upper dummy wafer support region 26b. In the embodiment, the term “a position lower than the uppermost dummy wafer Wd supported in the upper dummy wafer support region 26b” refers to a position at which the gas flow is not affected by the turbulent flow generated by the top plate 26d of the boat 26.

As shown in FIG. 3A, in the nozzle 44a, a lower end 47a of the slit 45a (also referred to as an upper end 46a of the gas supply port) is located at a position upper than the lowermost dummy wafer Wd supported in the lower dummy wafer support region 26c. In the embodiment, the term “a position upper than the lowermost dummy wafer Wd supported in the lower dummy wafer support region 26c” refers to a position at which the gas flow is not affected by the turbulent flow generated by the bottom plate 26e of the boat 26.

As shown in FIG. 3B, in the nozzle 44b, an upper end 46b of a uppermost gas supply hole in the plurality of gas supply holes 45b (also referred to as an upper end 46b of the gas supply port) provided in the nozzle 44b is located at a position lower than the uppermost dummy wafer Wd supported in the upper dummy wafer support region 26b.

As shown in FIG. 3B, in the nozzle 44b, a lower end 47b of a lowermost gas supply hole in the plurality of gas supply holes 45b (also referred to as a lower end 47b of the gas supply port) provided in the nozzle 44b is located at a position upper than the lowermost dummy wafer Wd supported in the lower dummy wafer support region 26c.

With the nozzles 44a and 44b having configurations described above, it is possible to suppress the influence of the turbulent flow of the gas generated by colliding with the top plate 26d or the bottom plate 26e of the boat 26. Thus, it is very effective in correcting the non-uniformity between the product wafers Wp.

Further, with the nozzles 44a and 44b having configurations described above, it is very effective in correcting the non-uniformity between the product wafers Wp as described below.

For example, when the product wafers Wp supported by the boat 26 are patterned wafers with high aspect ratios, the amount of the gas consumption increases in proportion to the pattern magnification. It is difficult to maintain dummy wafers that faithfully simulate such patterned wafers in terms of cost. Therefore, in practice, such dummy wafers Wd that require a smaller gas consumption per unit area than that of the product wafers Wp are used. That is, the dummy wafers Wd that consume a small amount of gas is used whereas the product wafers Wp consume a large amount of the gas.

Therefore, the gas consumption increases and the gas becomes insufficient in the product wafer support region 26a, while the gas consumption in the upper dummy wafer support region 26b and the lower dummy wafer support region 26c is small compared with that of the product wafer support region 26a. Thus, a surplus gas is generated in the upper dummy wafer support region 26b and the lower dummy wafer support region 26c. As a result, a thickness of a film formed on patterns of a product wafer Wd located in the vicinity of the upper dummy wafer support region 26b or the lower dummy wafer support region 26c is increased by the surplus gas, which may deteriorate the uniformity between the product wafers Wp. This phenomenon is remarkable particularly at an upper portion of the boat 26. This is because, the gas is diluted in a lower portion of the boat 26 by supplying the inert gas through the supply pipe 36e penetrating the lid 22 and a flow velocity of the gas in the lower portion of the boat 26 is lower than that of the gas in the upper portion of the boat 26 by the influence of the exhaust pipe 46.

As describe above, the dummy wafers Wd without pattern is used in the embodiment. However, dummy wafers Wd with patterns formed thereon may be used in the embodiment. As described above, the amount of the gas consumption of the dummy wafers Wd without pattern is smaller than that of the product wafers Wp. Likewise, the amount of the gas consumption of the dummy wafers Wd with patterns formed thereon is smaller than that of the product wafers Wp. Since, for example, a dummy wafer Wd with patterns is used repeatedly and/or its surface area including the patterns is smaller than that of a product wafer Wp because of the cost issue, the amount of the gas consumption of the dummy wafer Wd with patterns is smaller than that of the product wafer Wp. Therefore, the uniformity between the product wafers Wp may be deteriorated not only when the dummy wafers Wd without pattern are used but also when the dummy wafers Wd with patterns are used.

However, when the upper end 46a and the lower end 47a of the slit 45 in the nozzle 44a is located at positions as described above and the upper end 46b of the uppermost gas supply hole and the lower end 47b of the lowermost gas supply hole in the plurality of gas supply holes 45b provided in the nozzle 44b is located position as described above, it is possible to reduce the amount of the gas supplied to the upper dummy wafer support region 26b and the lower dummy wafer support region 26c. Therefore, even if the product wafers Wp with patterns formed thereon are used, it is possible to correct the non-uniformity between the product wafers Wp.

In particular, in the nozzles 44a and 44b having the above-described configurations, it is possible to reduce the amount of the gas supplied to the upper dummy wafer support region 26b by adjusting at least the positions of the upper end 46a of the slit 45a and the upper end 46b of the uppermost gas supply hole in the plurality of gas supply holes 45b. Thus, even if the deterioration of the uniformity between the product wafers Wp is remarkable in the upper portion of the boat 26, it is very effective in correcting the deterioration of the uniformity between the product wafers Wp.

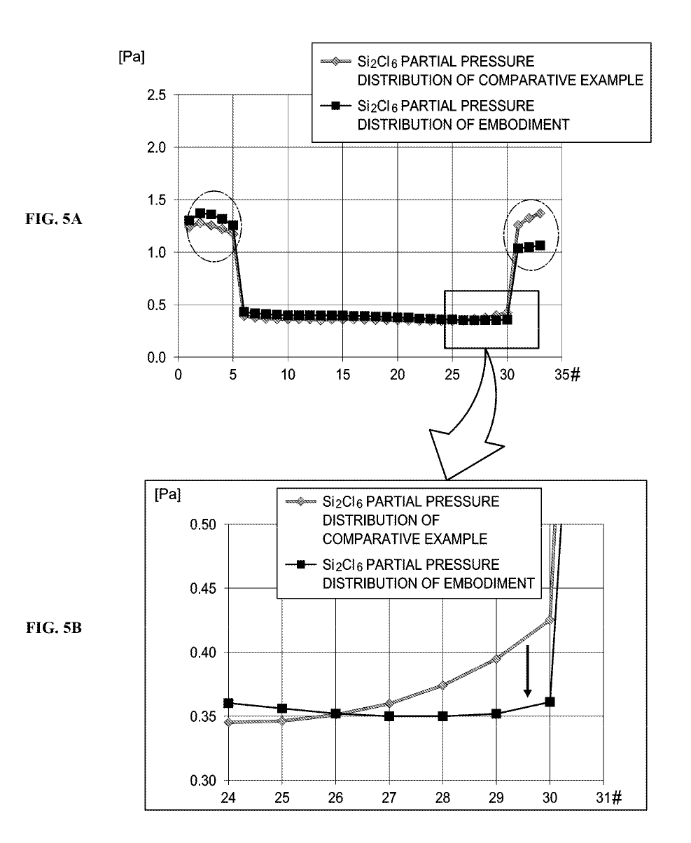

Hereinafter, a partial pressure distribution of the gas when the gas is actually supplied will be specifically described with reference to FIGS. 5A and 5B. For example, described below is a partial pressure distribution of the gas when the HCDS (Si₂Cl₆) gas serving as the source gas is supplied to the boat 26 in the process chamber 14 through the nozzle 44a according to the embodiment. Hereinafter, the partial pressure distribution of the gas when the HCDS (Si₂Cl₆) gas is supplied through the nozzle 44a is referred to as a “partial pressure distribution of Si₂Cl₆ according to the embodiment”. The partial pressure distribution of Si₂Cl₆ according to the embodiment is indicated by “Si₂Cl₆ PARTIAL PRESSURE DISTRIBUTION OF EMBODIMENT” in FIGS. 5A and 5B. For example, the slit 45a of the nozzle 44a is arranged such that the upper end 46a of the slit 45a is lower than the uppermost portion of the boat 26 by four slots (corresponding to four charged wafers). As a comparative example, described below is a partial pressure distribution of the gas when the HCDS (Si₂Cl₆) gas is supplied to the boat 26 in the process chamber 14 through a conventional nozzle. An upper end of the conventional nozzle is located at position upper than the uppermost portion of the boat 26. Hereinafter, the partial pressure distribution of the gas when the HCDS (Si₂Cl₆) gas is supplied through the conventional nozzle is referred to as a “partial pressure distribution of Si₂Cl₆ according to the comparative example”. The partial pressure distribution of Si₂Cl₆ according to the comparative example is indicated by “Si₂Cl₆ PARTIAL PRESSURE DISTRIBUTION OF COMPARATIVE EXAMPLE” in FIGS. 5A and 5B.

FIG. 5A schematically illustrates graphical representations of the partial pressure distribution of the Si₂Cl₆ according to the embodiment and the partial pressure distribution of the Si₂Cl₆ according to the comparative example, which are simulated with an analysis model. The vertical axis of FIG. 5A represents the partial pressure of the Si₂Cl₆ gas and the horizontal axis of FIG. 5A represents the slot number which corresponds to the relative height within the boat 26. In FIG. 5A, regions surrounded by dot-and-dash lines indicate the upper dummy wafer support region 26b and the lower dummy wafer support region 26c. FIG. 5B is an enlarged view of a portion indicated by a rectangular portion in FIG. 5A. Therefore, the same as in FIG. 5A, the vertical axis of FIG. 5B represents the partial pressure of the Si₂Cl₆ gas and the horizontal axis of FIG. 5B represents the slot number of the boat 26.

Referring to FIGS. 5A and 5B, as is clear from the enlarged view of FIG. 5B in particular, the partial pressure of the Si₂Cl₆ at the upper portion of the boat 26 is gradually increased in the partial pressure distribution of the Si₂Cl₆ according to the comparative example. However, the partial pressure of the Si₂Cl₆ at the upper portion of the boat 26 is relatively flat in the partial pressure distribution of the Si₂Cl₆ according to the embodiment (refer to an arrow shown in FIG. 5B).

As is clear from the above, according to the nozzle 44a having the configuration described in the embodiment, it is possible to reduce the amount of the gas supplied in the vicinity of the upper dummy wafer support region 26b where the deterioration of the uniformity between the product wafers Wp is particularly remarkable and to suppress the generation of the surplus gas in the vicinity of the upper dummy wafer support region 26b. The same applies to the nozzle 44b configured to supply the NH₃ gas serving as the reactive gas. Therefore, according to the nozzles 44a and 44b having the configurations described in the embodiment, even if the product wafers Wp with patterns are used, for example, it is possible to suppress the increase of the thickness of the film formed on the product wafers Wp in the boat 26, in particular, on the product wafers Wp in the vicinity of the upper dummy wafer support region 26b. That is, since it is possible to make the processed state uniform between the product wafers Wp, it is very effective in correcting the deterioration of the uniformity between the product wafers Wp and improving the uniformity between the product wafers Wp.

<Shape of Gas Supply Hole>

In the nozzles 44a and 44b configured to supply the gas such as the source gas and the reactive gas as described above, the slit 45a serving as the gas supply port that opens toward the wafers W is provided in the nozzle 44a, which is one of the nozzles 44a and 44b. As shown in FIG. 3A, the slit 45a is a vertically elongated slit-shaped hole extending continuously from the upper end 46a to the lower end 47a of the slit 45a.

In the nozzle 44a having the configuration described in the embodiment, the slit 45a serving as the gas supply port extends continuously from the upper end 46a to the lower end 47a of the slit 45a. Therefore, unlike a nozzle having a porous structure, an inner pressure of the tube constituting the nozzle 44a hardly vary with the position. Thus, it is possible to equalize the inner pressure of the tube constituting the nozzle 44a. In general, a gas pressure and a thermal decomposition temperature are proportional. That is, the thermal decomposition temperature of the gas increases as the gas pressure increases, which is apparent from, for example, the known saturated water vapor pressure curve. Therefore, according to the nozzle 44a capable of equalizing the inner pressure of the tube, it is possible to supply the gas decomposed uniformly between the product wafers Wp, thereby it is possible to improve the yield of substrate processing on the product wafers Wp.

As described above, the plurality of gas supply holes 45b opening toward the wafers W is provided in the other nozzle 44b. As shown in FIG. 3B, the plurality of gas supply holes 45b separated from one another are provided from the upper end 46b of the uppermost hole to the lower end 47b of the lowermost hole thereof.

In the nozzle 44b having the configuration described in the embodiment, the plurality of gas supply holes 45b separated from one another are provided from the upper end 46b of the uppermost hole to the lower end 47b of the lowermost hole thereof. Therefore, unlike a nozzle having a vertically elongated slit, it is possible to improve the strength of the nozzle 44b itself. Therefore, the nozzle 44b is particularly suitable for supplying the gas species having a high thermal decomposition temperature.

### Effects of the Embodiment

One or more advantageous effects described below are provided according to the embodiment.

(a) According to the embodiment, the gas is supplied while the dummy wafers Wd are arranged above and below the product wafers Wp. Therefore, it is possible to suppress the influence of the difference in the size of the turbulent flow that may be generated when the gas is supplied to the product wafers Wp. That is, by using the dummy wafers Wd, it is possible to improve the uniformity of the amount of the gas supplied to each of the product wafers Wp. Thus, the processed state can be made uniform between the product wafers Wp. As a result, it is possible to suppress the decrease in the yield of the substrate processing with respect to the product wafers Wp.

(b) According to the embodiment, the upper end 46a of the slit 45a provided in the nozzle 44a and the upper end 46b of the uppermost gas supply hole in the plurality of gas supply holes 45b provided in the nozzle 44b are all located at positions lower than the uppermost dummy wafer Wd supported in the upper dummy wafer support region 26b. That is, by using the dummy wafers Wd and by appropriately setting the positions of the upper end 46a of the slit 45a and the upper end 46b of the uppermost gas supply hole in the plurality of gas supply holes 45b such that the flow of the supplied gas does not collide with the top plate 26d of the boat 26, it is possible to reliably suppress the influence by the turbulent flow of the gas on the product wafers Wp. Therefore, it is possible to correct the non-uniformity between the product wafers Wp, and it is very effective in suppressing the decrease in the yield of the substrate processing on the product wafers Wp by making the processed state uniform between the product wafers Wp.

(c) According to the embodiment, by appropriately setting the positions of the upper end 46a of the slit 45a and the upper end 46b of the uppermost gas supply hole in the plurality of gas supply holes 45b, it is possible to reduce the amount of the gas supplied in the vicinity of the upper dummy wafer support region 26b where the deterioration of the uniformity between the product wafers Wp is particularly remarkable and to suppress the generation of the surplus gas in the vicinity of the upper dummy wafer support region 26b. That is, for example, even if the product wafers Wp with patterns are used, it is possible to suppress the increase of the thickness of the film formed on the product wafers Wp in the boat 26, in particular, on the product wafers Wp in the vicinity of the upper dummy wafer support region 26b. Thus, even if the deterioration of the uniformity between the product wafers Wp is remarkable in the upper portion of the boat 26, it is very effective in correcting the deterioration of the uniformity between the product wafers Wp and improving the uniformity between the product wafers Wp. Therefore, it is possible to make the processed state more uniform between the product wafers Wp, thereby it is very effective in further suppressing the decrease in the yield of the substrate processing on the product wafers Wp.

(d) According to the embodiment, the lower end 47a of the slit 45a provided in the nozzle 44a and the lower end 47b of the lowermost gas supply hole in the plurality of gas supply holes 45b provided in the nozzle 44b are all located at positions upper than the lowermost dummy wafer Wd supported in the lower dummy wafer support region 26c. That is, by using the dummy wafers Wd and by adjusting the positions of the lower end 47a of the slit 45a and the lower end 47b of the lowermost gas supply hole in the plurality of gas supply holes 45b such that the flow of the supplied gas does not collide with the bottom plate 26e of the boat 26, it is possible to reliably suppress the influence by the turbulent flow of the gas on the product wafers Wp. Therefore, it is possible to correct the non-uniformity between the product wafers Wp, and it is very effective in suppressing the decrease in the yield of the substrate processing on the product wafers Wp by making the processed state uniform between the product wafers Wp.

(e) According to the embodiment, the slit 45a serving as the gas supply port of the nozzle 44a is shaped as an elongated hole extending continuously from the upper end 46a to the lower end 47a of the slit 45a. Therefore, the inner pressure of the tube constituting the nozzle 44a is hardly deviated and it is possible to equalize the inner pressure of the tube constituting the nozzle 44a. As a result, it is possible to supply the gas between the product wafers Wp through the slit 45a of the nozzle 44a when the gas is decomposed thermally and uniformly by the equalized inner pressure. Thus, it is possible to improve the yield of the substrate processing on the product wafers Wp. Since the thermal decomposition of the source gas may affect the uniformity between the product wafers Wp, the above-described hole shape of the slit 45a is particularly effective when it is applied to the nozzle 44a configured to supply the source gas.

(f) According to the embodiment, the plurality of gas supply holes 45b of the nozzle 44b serving as the gas supply port has a porous structure where the plurality of holes separated from one another are provided from the upper end 46b of the uppermost hole to the lower end 47b of the lowermost hole thereof. Therefore, it is possible to improve the strength of the nozzle 44b itself. Therefore, the nozzle 44b with the plurality of gas supply holes 45b is particularly preferable when it is used for supplying the gas species whose thermal decomposition temperature is not problematic.

(g) According to the embodiment, the cylindrical portion 14a, the lid 14b, the storage body 14c and the duct body 14d constituting the process chamber 14 are formed as an integrated body made of a material having heat resistance and corrosion resistance. The diameter of the cylindrical portion 14a is so small that the nozzles 44a and 44b cannot be inserted in the gap between the cylindrical portion 14a and the wafers W accommodated in the process chamber 14 coaxially with the cylindrical portion 14a. Thereby, it is possible to reliably generate the gas flow described above in the process chamber 14. That is, by narrowing the gap between the product wafers Wp and the cylindrical portion 14a, it is possible to suppress the influence by the turbulent flow on the product wafers Wp and to reliably make the processed state uniform between the product wafers Wp.

### Modified Examples

While the technique is described in detail by way of the embodiment, the above-described technique is not limited thereto. The above-described technique may be modified in various ways without departing from the gist thereof.

While the embodiment is described by way of an example wherein the HCDS gas is used as the source gas, the above-described technique is not limited thereto. For example, preferably, the nozzle according to the embodiment can be used for supplying a gas serving as the source gas when the gas affect the uniformity between the wafers as the gas decomposes. For example, preferably, the nozzle according to the embodiment can be used for supplying a gas with decomposition temperature close to the processing temperature.

While the HCDS gas is exemplified as the source gas according to the embodiment, the above-described technique is not limited thereto. Instead of the HCDS gas, for example, an inorganic halosilane source gas such as a dichlorosilane (SiH₂Cl₂, abbreviated as DCS) gas, a monochlorosilane (SiH₃Cl, abbreviated as MCS) gas and a trichlorosilane (SiHCl₃, abbreviated as TCS) gas may be used as the source gas. Instead of the HCDS gas, for example, an amino-based (amine-based) silane source gas free of halogen such as a trisdimethylaminosilane (Si[N(CH₃)₂]₃H, abbreviated as 3DMAS) gas and a bis(tertiary-butyl amino)silane gas (SiH₂[NH(C₄H₉)]₂, abbreviated as BTBAS) gas may be used as the source gas. Instead of the HCDS gas, for example, an inorganic silane source gas free of halogen such as a monosilane (SiH₄, abbreviated as MS) gas and a disilane (Si₂H₆, abbreviated as DS) gas.

For example, the above-described technique may be applied to the formations of a metal-based film, that is, a film containing a metal element such as titanium (Ti), zirconium (Zr), hafnium (Hf), tantalum (Ta), niobium (Nb), aluminum (Al), molybdenum (Mo) and tungsten (W).

The above-described embodiment and the modified examples may be appropriately combined.

### Preferred Embodiments of Technique

Preferred embodiments of the technique will be supplementarily described below.

<Supplementary note 1>

According to one aspect of the technique described herein, there is provided a substrate processing apparatus including:

a substrate retainer including:
a product wafer support region configured to support product wafers with patterns formed thereon in a state where the product wafers are stacked;
an upper dummy wafer support region configured to support dummy wafers above the product wafer support region; and
a lower dummy wafer support region configured to support dummy wafers below the product wafer support region;

a process chamber accommodating the substrate retainer;

a gas supply system, configured to supply a gas to the substrate retainer, including:
a tubular nozzle vertically extending along the substrate retainer accommodated in the process chamber; and
a gas supply port provided at the nozzle; and

an exhaust system configured to exhaust an atmosphere of the process chamber,

wherein an upper end of the gas supply port is located at a position lower than an uppermost dummy wafer disposed in the upper dummy wafer support region.

<Supplementary Note 2>

In the substrate processing apparatus of Supplementary note 1, it is preferable that a lower end of the gas supply port is located at a position upper than a lowermost dummy wafer disposed in the lower dummy wafer support region.

<Supplementary Note 3>

In the substrate processing apparatus of one of Supplementary notes 1 and 2, it is preferable that the gas supply port includes a slit extending continuously from the upper end to the lower end of the gas supply port.

<Supplementary Note 4>

In the substrate processing apparatus of one of Supplementary notes 1 and 2, it is preferable that the gas supply port includes a plurality of holes provided separately from one another from the upper end to the lower end of the gas supply port.

<Supplementary Note 5>

In the substrate processing apparatus of one of Supplementary notes 1 through 4, it is preferable that the process chamber includes:

a cylindrical portion surrounding an outer peripheral portion of the substrate retainer;

a flat plate-shaped lid configured to close an upper end of the cylindrical portion;

a storage body protruding outward from a first side portion of the cylindrical portion to define a blocking space and accommodate the nozzle; and

a duct body protruding outward from a second side portion of the cylindrical portion located opposite to the first side portion to define a blocked exhaust path,

wherein the cylindrical portion, the lid, the storage body and the duct body are formed as an integrated body made of a material having heat resistance and corrosion resistance, and

a diameter of the cylindrical portion is so small as to make it impossible to insert the nozzle in a gap between the cylindrical portion and the product wafers accommodated in the process chamber coaxially with the cylindrical portion.

<Supplementary Note 6>

According to another aspect of the technique described herein, there is provided a method of manufacturing a semiconductor device by using a substrate retainer including a product wafer support region configured to support product wafers with patterns formed thereon in a state where the product wafers are stacked; an upper dummy wafer support region configured to support dummy wafers above the product wafer support region; and a lower dummy wafer support region configured to support dummy wafers below the product wafer support region, including:

loading the product wafers into the product wafer support region, and the dummy wafers respectively into the upper dummy wafer support region and the lower dummy wafer support region;

transferring the substrate retainer accommodating the product wafers and the dummy wafers into a process chamber accommodating the substrate retainer; and

processing the product wafers by performing a gas supply to the substrate retainer from a gas supply system including: a tubular nozzle vertically extending along the substrate retainer accommodated in the process chamber; and a gas supply port provided at the nozzle, wherein an upper end of the gas supply port is located at a position lower than an uppermost dummy wafer disposed in the upper dummy wafer support region.

<Supplementary Note 7>

According to another aspect of the technique described herein, there is provided a program that, by using a substrate retainer including a product wafer support region configured to support product wafers with patterns formed thereon in a state where the product wafers are stacked; an upper dummy wafer support region configured to support dummy wafers above the product wafer support region; and a lower dummy wafer support region configured to support dummy wafers below the product wafer support region, causes a computer to execute:

loading the product wafers into the product wafer support region, and the dummy wafers respectively into the upper dummy wafer support region and the lower dummy wafer support region;

transferring the substrate retainer accommodating the product wafers and the dummy wafers into a process chamber accommodating the substrate retainer; and

processing the product wafers by performing a gas supply to the substrate retainer from a gas supply system including: a tubular nozzle vertically extending along the substrate retainer accommodated in the process chamber; and a gas supply port provided at the nozzle, wherein an upper end of the gas supply port is located at a position lower than an uppermost dummy wafer disposed in the upper dummy wafer support region.

According to the technique described herein, it is possible to improve uniformity between substrates.

What is claimed is:

1. A substrate processing apparatus comprising:
a substrate retainer comprising:
a product wafer support region configured to support product wafers with patterns formed thereon in a state where the product wafers are stacked;
an upper dummy wafer support region configured to support dummy wafers above the product wafer support region; and
a lower dummy wafer support region configured to support dummy wafers below the product wafer support region;
a process chamber accommodating the substrate retainer;
a gas supply system, configured to supply a gas to the substrate retainer, comprising:
a tubular nozzle vertically extending along the substrate retainer accommodated in the process chamber; and
a gas supply port provided at the nozzle; and
an exhaust system configured to exhaust an atmosphere of the process chamber,
wherein an upper end of the gas supply port is located at a position lower than an uppermost dummy wafer disposed in the upper dummy wafer support region.

2. The substrate processing apparatus of claim 1, wherein a lower end of the gas supply port is located at a position upper than a lowermost dummy wafer disposed in the lower dummy wafer support region.

3. The substrate processing apparatus of claim 2, wherein the gas supply port comprises a slit extending continuously from the upper end to the lower end of the gas supply port.

4. The substrate processing apparatus of claim 3, wherein the process chamber comprises:
a cylindrical portion surrounding an outer peripheral portion of the substrate retainer;
a flat plate-shaped lid configured to close an upper end of the cylindrical portion;
a storage body protruding outward from a first side portion of the cylindrical portion to define a blocking space and accommodate the nozzle; and
a duct body protruding outward from a second side portion of the cylindrical portion located opposite to the first side portion to define a blocked exhaust path,
wherein the cylindrical portion, the lid, the storage body and the duct body are formed as an integrated body made of a material having heat resistance and corrosion resistance, and
a diameter of the cylindrical portion is so small as to make it impossible to insert the nozzle in a gap between the cylindrical portion and the product wafers accommodated in the process chamber coaxially with the cylindrical portion.

5. The substrate processing apparatus of claim 2, wherein the gas supply port comprises a plurality of holes provided separately from one another from the upper end to the lower end of the gas supply port.

6. The substrate processing apparatus of claim 5, wherein the process chamber comprises:
a cylindrical portion surrounding an outer peripheral portion of the substrate retainer;
a flat plate-shaped lid configured to close an upper end of the cylindrical portion;
a storage body protruding outward from a first side portion of the cylindrical portion to define a blocking space and accommodate the nozzle; and
a duct body protruding outward from a second side portion of the cylindrical portion located opposite to the first side portion to define a blocked exhaust path,
wherein the cylindrical portion, the lid, the storage body and the duct body are formed as an integrated body of a material having heat resistance and corrosion resistance, and
a diameter of the cylindrical portion is so small as to make it impossible to insert the nozzle in a gap between the cylindrical portion and the product wafers accommodated in the process chamber coaxially with the cylindrical portion.

7. The substrate processing apparatus of claim 2, wherein the process chamber comprises:
a cylindrical portion surrounding an outer peripheral portion of the substrate retainer;
a flat plate-shaped lid configured to close an upper end of the cylindrical portion;
a storage body protruding outward from a first side portion of the cylindrical portion to define a blocking space and accommodate the nozzle; and
a duct body protruding outward from a second side portion of the cylindrical portion located opposite to the first side portion to define a blocked exhaust path,
wherein the cylindrical portion, the lid, the storage body and the duct body are formed as an integrated body of a material having heat resistance and corrosion resistance, and
a diameter of the cylindrical portion is so small as to make it impossible to insert the nozzle in a gap between the cylindrical portion and the product wafers accommodated in the process chamber coaxially with the cylindrical portion.

8. The substrate processing apparatus of claim 1, wherein the gas supply port comprises a slit extending continuously from the upper end to the lower end of the gas supply port.

9. The substrate processing apparatus of claim 8, wherein the process chamber comprises:
a cylindrical portion surrounding an outer peripheral portion of the substrate retainer;
a flat plate-shaped lid configured to close an upper end of the cylindrical portion;
a storage body protruding outward from a first side portion of the cylindrical portion to define a blocking space and accommodate the nozzle; and
a duct body protruding outward from a second side portion of the cylindrical portion located opposite to the first side portion to define a blocked exhaust path,
wherein the cylindrical portion, the lid, the storage body and the duct body are formed as an integrated body of a material having heat resistance and corrosion resistance, and
a diameter of the cylindrical portion is so small as to make it impossible to insert the nozzle in a gap between the cylindrical portion and the product wafers accommodated in the process chamber coaxially with the cylindrical portion.

10. The substrate processing apparatus of claim 1, wherein the gas supply port comprises a plurality of holes provided separately from one another from the upper end to the lower end of the gas supply port.

11. The substrate processing apparatus of claim 10, wherein the process chamber comprises:
a cylindrical portion surrounding an outer peripheral portion of the substrate retainer;
a flat plate-shaped lid configured to close an upper end of the cylindrical portion;
a storage body protruding outward from a first side portion of the cylindrical portion to define a blocking space and accommodate the nozzle; and
a duct body protruding outward from a second side portion of the cylindrical portion located opposite to the first side portion to define a blocked exhaust path,
wherein the cylindrical portion, the lid, the storage body and the duct body are formed as an integrated body of a material having heat resistance and corrosion resistance, and
a diameter of the cylindrical portion is so small as to make it impossible to insert the nozzle in a gap between the cylindrical portion and the product wafers accommodated in the process chamber coaxially with the cylindrical portion.

12. The substrate processing apparatus of claim 1, wherein the process chamber comprises:
a cylindrical portion surrounding an outer peripheral portion of the substrate retainer;
a flat plate-shaped lid configured to close an upper end of the cylindrical portion;
a storage body protruding outward from a first side portion of the cylindrical portion to define a blocking space and accommodate the nozzle; and
a duct body protruding outward from a second side portion of the cylindrical portion located opposite to the first side portion to define a blocked exhaust path,
wherein the cylindrical portion, the lid, the storage body and the duct body are formed as an integrated body of a material having heat resistance and corrosion resistance, and
a diameter of the cylindrical portion is so small as to make it impossible to insert the nozzle in a gap between the cylindrical portion and the product wafers accommodated in the process chamber coaxially with the cylindrical portion.
